(19) United States
(12) Patent Application Publication
(10) Pub. No.: US 2025/0221003 A1
(43) Pub. Date: Jul. 3, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Masato NOBORIO, Nisshin-shi (JP); Toshiki MII, Nisshin-shi (JP)

(21) Appl. No.: 18/910,099

(22) Filed: Oct. 9, 2024

(30) Foreign Application Priority Data
Dec. 28, 2023 (JP) 2023-223137

(51) Int. Cl. H01L 29/423; H01L 29/78

(52) U.S. Cl. CPC H10D 64/516; H10D 30/668

(57) ABSTRACT

An insulating film has an inclined portion whose thickness gradually increases as extending away from an active region. The insulating film has a first corner where the thickness begins to increase, on a first surface opposite to a semiconductor substrate. A gate electrode is extended from the active region to a peripheral region and is arranged on the inclined portion. A recess of the semiconductor substrate has an open end at a position corresponding to the first corner. The insulating film is arranged in the recess to cover the open end, and has a second corner on a second surface adjacent to the semiconductor substrate.

### CROSS REFERENCE TO RELATED APPLICATION

This application is based on Japanese Patent Application No. 2023-223137 filed on Dec. 28, 2023, the disclosure of which is incorporated herein by reference.

### TECHNICAL FIELD

The present disclosure relates to a semiconductor device.

### BACKGROUND

A semiconductor device includes a switching element having a gate electrode. The semiconductor device includes a semiconductor substrate, and has an active region in which the switching element is located, and a peripheral region surrounding the active region.

### SUMMARY

According to one aspect of the present disclosure, a semiconductor device has an active region and a peripheral region surrounding an outer periphery of the active region. The semiconductor device includes: a semiconductor substrate having the active region and the peripheral region; a switching element formed in the active region and having a gate electrode with one direction as a longitudinal direction; and an insulating film formed in the peripheral region. The insulating film has a first surface opposite to the semiconductor substrate and a second surface adjacent to the semiconductor substrate. The insulating film has an inclined portion whose thickness gradually increases as extending away from the active region. The insulating film has a first corner at which the thickness of the insulating film begins to increase on the first surface. The gate electrode is extended from the active region to the peripheral region and is located on the inclined portion of the insulating film. The semiconductor substrate has a recess, and an open end of the recess is located at a position corresponding to the first corner. The insulating film is arranged in the recess so as to cover the open end. The insulating film has a second corner on the second surface to cover the open end.

### BRIEF DESCRIPTION OF DRAWINGS

FIG. 1 is a plan view of a semiconductor device according to a first embodiment.

FIG. 2 is a cross-sectional view taken along line II-II in FIG. 1.

FIG. 3 is a cross-sectional view taken along line III-III in FIG. 1.

FIG. 4 is an enlarged view of an area IV in FIG. 3.

FIG. 5 is an enlarged view of a vicinity of an inclined portion in a comparative semiconductor device.

FIG. 6 is a schematic diagram showing a displacement current in a comparative semiconductor device.

FIG. 7 is a diagram showing an electric field along line VII-VII in FIG. 5.

FIG. 8 is a diagram showing a relationship between a depth of a recess and an electric field.

FIG. 9 is a diagram showing a relationship between a position of a second corner and an electric field.

FIG. 10 is an enlarged view of a vicinity of an inclined portion in a second embodiment.

FIG. 11 is a diagram showing a relationship between a second angle and an electric field in a third embodiment.

FIG. 12 is an enlarged view of a vicinity of an inclined portion in a fourth embodiment.

FIG. 13A is an enlarged view of a vicinity of an inclined portion in a modification of the fourth embodiment.

FIG. 13B is an enlarged view of a vicinity of an inclined portion in a modification of the fourth embodiment.

### DETAILED DESCRIPTION

A semiconductor device includes a switching element having a gate electrode, and a semiconductor substrate. The semiconductor device has an active region in which the switching element having the gate electrode is formed, and a peripheral region surrounding the active region. In the peripheral region, an insulating film is formed on a first surface of the semiconductor substrate, and the gate electrode is extended onto the insulating film.

Specifically, a part of the insulating film adjacent to the active region has a sloped portion whose thickness gradually increases as extending away from the active region. The gate electrode extends along the sloped portion to an area where the insulating film is thick.

However, in such a semiconductor device, a corner is formed at a part of the insulating film where the thickness of the inclined portion begins to increase. In this case, when the semiconductor device is switched from an on state to an off state, for example, a large electric field is applied to the corner of the insulating film, which may destroy the insulating film.

The present disclosure provides a semiconductor device in which a breakdown of an insulating film is suppressed.

According to one aspect of the present disclosure, a semiconductor device has an active region and a peripheral region surrounding an outer periphery of the active region. The semiconductor device includes: a semiconductor substrate having the active region and the peripheral region; a switching element formed in the active region and having a gate electrode with one direction as a longitudinal direction; and an insulating film formed in the peripheral region. The insulating film has a first surface opposite to the semiconductor substrate and a second surface adjacent to the semiconductor substrate. The insulating film has an inclined portion whose thickness gradually increases as extending away from the active region. The insulating film has a first corner at which the thickness of the insulating film begins to increase on the first surface. The gate electrode is extended from the active region to the peripheral region and is located on the inclined portion of the insulating film. The semiconductor substrate has a recess, and an open end of the recess is located at a position corresponding to the first corner. The insulating film is arranged in the recess so as to cover the open end. The insulating film has a second corner on the second surface to cover the open end.

Accordingly, the insulating film has the second corner formed at the position corresponding to the first corner. This makes it possible to increase the number of locations in the insulating film where the electric field is concentrated, and to reduce the maximum electric field applied to the insulating film, thereby making it possible to restrict the insulating film from being destroyed.

Hereinafter, embodiments of the present disclosure will be described with reference to the drawings. In the following embodiments, the same or equivalent parts are denoted by the same reference numerals as each other, and explanations will be provided to the same reference numerals.

### First Embodiment

A first embodiment will be described with reference to the drawings. A semiconductor device of this embodiment is preferably mounted on a vehicle, for example, to control various electronic components.

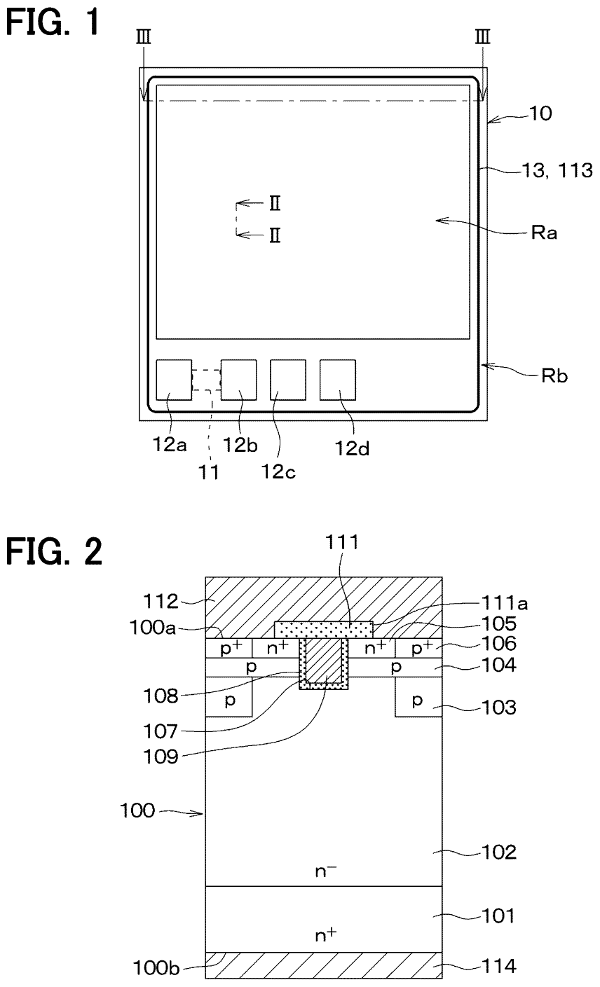

As shown in FIG. 1, the semiconductor device of this embodiment has an active region Ra and a peripheral region Rb located outside the active region Ra. A switching element is formed in the active region Ra, as a semiconductor element. In this embodiment, a vertical MOSFET is formed as a switching element. MOSFET is an abbreviation for Metal Oxide Semiconductor Field Effect Transistor.

More specifically, the semiconductor device of this embodiment has a rectangular shape in the top view. In the semiconductor device, an internal region including a central portion is defined as the active region Ra, and the peripheral region Rb is disposed to surround the active region Ra. In FIG. 1, the area surrounded by a square indicates the active region Ra, and a thick solid line indicates a gate liner 13 in the peripheral region Rb surrounding the active region Ra. The gate liner 13 includes a gate lead-out portion 109a of a gate electrode 109 and a gate wiring layer 113, which will be described later, in the vertical MOSFET. In this embodiment, the gate liner 13 is disposed in the peripheral region Rb located on the outer periphery of the active region Ra.

The peripheral region Rb is provided with a temperature sensor 11 such as a temperature sensing diode and pads 12a to 12d. The pads 12a to 12d are, for example, from the left side in FIG. 1, a cathode pad 12a, an anode pad 12b, a sense pad 12c, and a gate pad 12d. The semiconductor device is electrically connected to the outside by connecting each of the pads 12a to 12d to bonding wires (not shown).

Next, the cross-sectional structure of the semiconductor device will be described with reference to FIGS. 2 to 4.

The semiconductor device includes a semiconductor substrate 100 having an n+ type substrate 101 made of a semiconductor material such as SiC or Si. In the following, for example, the substrate 101 is made of SiC. In this embodiment, the substrate 101 constitutes a drain region.

An n− type drift layer 102 having a lower impurity concentration than the substrate 101 is epitaxially grown on the surface of the substrate 101. In the surface layer portion of the drift layer 102, p-type deep layers 103 are formed at a predetermined interval. A p-type base region 104 is formed on the drift layer 102 and the deep layer 103, and an n+ type source region 105 and a p+ type contact region 106 are formed on the base region 104. In this embodiment, the source region 105 is formed on a portion of the drift layer 102 corresponding to a region in which the deep layer 103 is not formed, and the contact region 106 is formed on a portion of the drift layer 102 corresponding to a region in which the deep layer 103 is formed.

In this embodiment, the semiconductor substrate 100 includes the substrate 101, the drift layer 102, the deep layer 103, the base region 104, the source region 105, and the contact region 106. In the following description, one surface of the semiconductor substrate 100 adjacent to the source region 105 and the contact region 106 is referred to as the first surface 100a, and the other surface of the semiconductor substrate 100 adjacent to the substrate 101 is referred to as the second surface 100b.

A gate trench 107 is formed in the semiconductor substrate 100 from the first surface 100a. Specifically, the gate trench 107 is formed to penetrate the source region 105 and the base region 104 and reach the drift layer 102. Therefore, the source region 105 and the base region 104 are formed in contact with the side surface of the gate trench 107. The contact region 106 is disposed on the opposite side of the gate trench 107 through the source region 105.

The gate trench 107 is provided in a linear layout in FIG. 2, in which a lateral direction corresponds to a width direction, and an up-down direction corresponds to a depth direction. The gate trench 107 has a longitudinal direction perpendicular to the width direction and the depth direction. Although FIG. 2 shows only one gate trench 107, in reality, multiple gate trenches 107 are arranged at equal interval in the left-right direction of FIG. 2, in an interposed manner between the deep layers 103, to form a stripe shape.

A portion of the base region 104 located on the side surface of the gate trench 107 serves as a channel region that connects the source region 105 and the drift layer 102 when the vertical MOSFET is in operation. A gate insulating film 108 is formed on an inner wall surface of the gate trench 107 including the channel region. A gate electrode 109 composed of doped polysilicon is formed on a surface of the gate insulating film 108, and the gate insulating film 108 and the gate electrode 109 are embedded in the gate trench 107. Therefore, the gate electrode 109 is extended with the same direction as the longitudinal direction of the gate trench 107. Thus, the trench gate structure is formed.

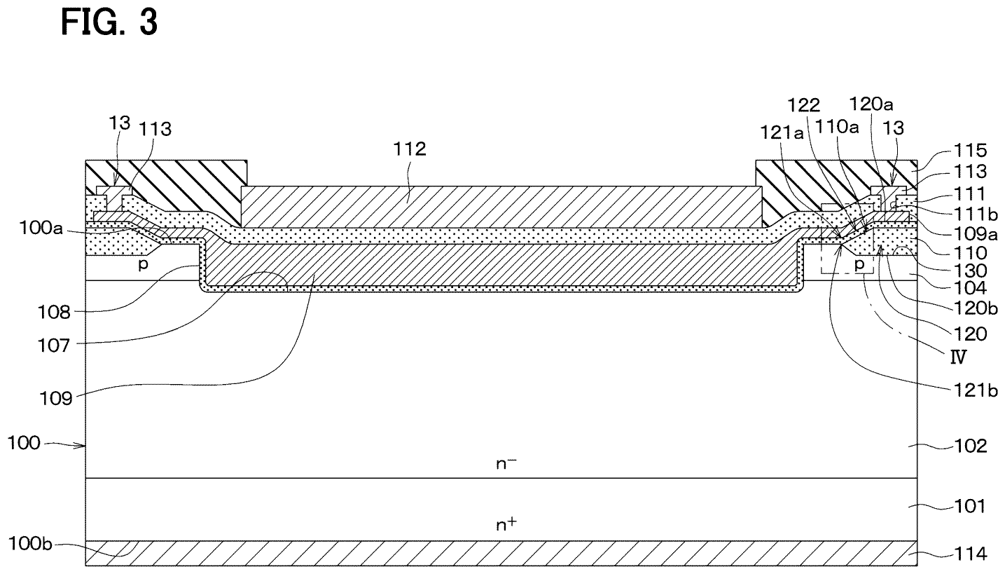

The trench gate structure extends in the left-right direction of FIG. 1. As shown in FIG. 3, the trench gate structure is formed to extend from the active region Ra to the peripheral region Rb. The source region 105 is formed in contact with the side surface of the gate trench 107, but is formed only in the active region Ra and not in the peripheral region Rb. Therefore, the channel region is formed only in the active region Ra.

As shown in FIG. 3, a field insulating film 110 is formed on at least the side of the rectangular active region Ra located at the tip of the trench gate structure, on the surface of the base region 104, at a position away from both tips of the gate trench 107. The field insulating film 110 is open to the active region Ra, and has an end portion extending in a direction intersecting the longitudinal direction of the trench gate structure. That is, the field insulating film 110 has a shape in which the open end positioned on the left/right side of FIG. 1 opposes the tip of the trench gate structure. Although not shown in FIG. 3, the open end of the field insulating film 110 is formed along the upper/lower side of the rectangular active region Ra in FIG. 1.

The field insulating film 110 is made thick so as not easily be broken down even when a high voltage is applied. In this embodiment, the gate insulating film 108 formed in the gate trench 107 is extended to outside the gate trench 107 and extends onto the surface of the field insulating film 110.

Specifically, the field insulating film 110 has an inclined portion 110a in which the end adjacent to the active region Ra, that is, on the trench gate structure is inclined obliquely. In this embodiment, the inclined portion 110a of the field insulating film 110 is formed such that the thickness gradually increases from the active region Ra toward the peripheral region Rb. In this embodiment, the gate insulating film 108 is formed on the field insulating film 110 including the inclined portion 110a.

Like the gate insulating film 108, the gate electrode 109 is extended inside the gate trench 107, and further extended from both ends of the gate trench 107 in the longitudinal direction to the outside of the gate trench 107. The gate electrode 109 is extended to a position where the thickness of the field insulating film 110 is increased. A portion of the gate electrode 109 that is drawn out to the outside of the gate trench 107 constitutes a gate lead-out portion 109a which is a part of the gate liner 13.

Specifically, the gate lead-out portion 109a of the gate electrode 109 is formed on the field insulating film 110 including the inclined portion 110a, and is disposed to extend up to the field insulating film 110 which is formed thick. Therefore, the inclined portion 110a of the field insulating film 110 is located under the gate electrode 109.

If the inclined portion 110a is not formed at the end of the field insulating film 110, the gate electrode 109 would be easily thinned at the step portion at the end of the field insulating film 110, and a step discontinuity would be easily generated. However, in this embodiment, since the inclined portion 110a is formed at the end of the field insulating film 110, it is possible to restrict the gate electrode 109 from being disconnected due to a step at the end of the field insulating film 110. The gate electrode 109 is prone to breakage when the thickness of the gate electrode 109 is thinner than that of the field insulating film 110. However, even in such a case, the configuration of this embodiment can restrict the breakage.

The gate insulating film 108 can be appropriately patterned, and therefore does not necessarily have to be formed on the surface of the field insulating film 110. For example, the gate insulating film 108 may be terminated at the end of the field insulating film 110 and may not be disposed on the field insulating film 110. Alternatively, the gate insulating film 108 may be formed on the base region 104, and the field insulating film 110 may be formed on the gate insulating film 108. That is, in the peripheral region Rb, the gate insulating film 108 may be disposed between the field insulating film 110 and the semiconductor substrate 100.

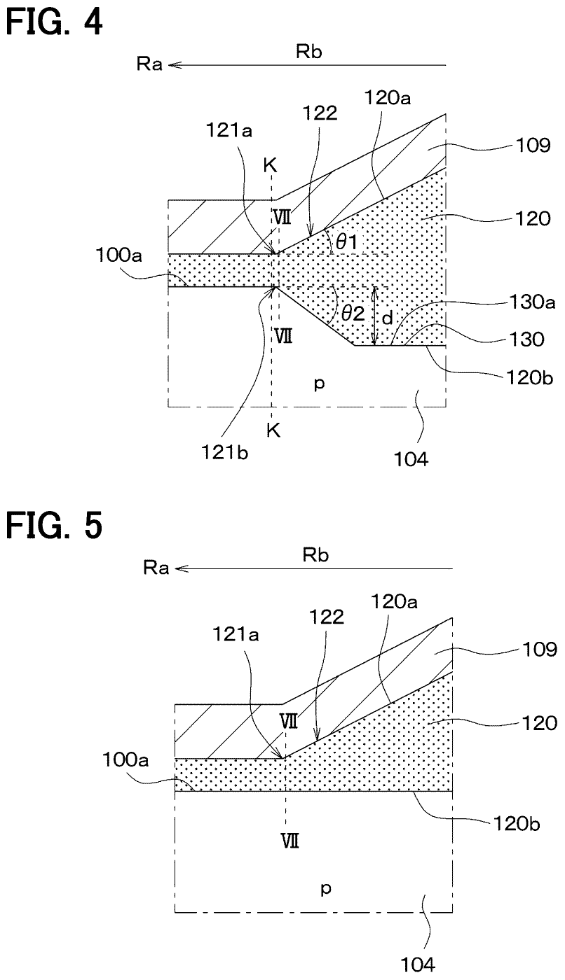

In this embodiment, as shown in FIGS. 3 and 4, a recess 130 is formed in the first surface 100a of the semiconductor substrate 100 in the peripheral region Rb. Hereinafter, in the peripheral region Rb, an insulating film located between the first surface 100a of the semiconductor substrate 100 and the gate electrode 109 will be simply referred to as an insulating film 120. One surface of the insulating film 120 opposite to the first surface 100a of the semiconductor substrate 100 will be referred to as a first surface 120a, and the other surface of the insulating film 120 adjacent to the first surface 100a of the semiconductor substrate 100 will be referred to as a second surface 120b.

In this embodiment, the gate insulating film 108 is formed on the surface of the field insulating film 110. Therefore, the insulating film 120 of this embodiment includes the field insulating film 110 and the gate insulating film 108, and the first surface 120a is configured by the gate insulating film 108. FIG. 4 is an enlarged view of an area IV in FIG. 3, but for ease of understanding, only the semiconductor substrate 100, the insulating film 120, and the gate electrode 109 are shown. In addition, the peripheral region Rb is configured such that the base region 104 serving as a second semiconductor layer is disposed on the drift layer 102 serving as a first semiconductor layer, and the insulating film 120 is disposed on the base region 104. In addition, the active region Ra is configured such that the source region 105 serving as a third semiconductor layer is formed in the surface layer portion of the base region 104, and the gate electrode 109 is arranged on the surface of the base region 104 interposed between the drift layer 102 and the source region 105.

The thickness of the insulating film 120 is gradually increased from the active region Ra since the inclined portion 110a is formed at the end of the field insulating film 110. Therefore, the first surface 120a of the insulating film 120 has an inclined portion 122 corresponding to the inclined portion 110a, and a first corner 121a is formed at the position where the thickness starts to increase.

The recess 130 has an open end at a position corresponding to the first corner 121a formed on the first surface 100a of the semiconductor substrate 100, and the insulating film 120 is disposed to fill the recess 130. Therefore, on the second surface 120b of the insulating film 120, a second corner 121b is formed at the open end of the recess 130. That is, in this embodiment, the insulating film 120 has the first corner 121a formed on the first surface 120a and the second corner 121b formed on the second surface 120b. The recess 130 has a bottom surface 130a which is substantially parallel to the first surface 100a of the semiconductor substrate 100. Further, the recess 130 is formed such that the bottom surface 130a extends beyond the second corner 121b (i.e., the first corner 121a) toward the opposite side to the active region Ra. The recess 130 is formed at a position corresponding to the first corner 121a, along the upper/lower side of the active region Ra which is rectangular in shape in FIG. 1. The position where the second corner 121b is formed (i.e., the position where the recess 130 is formed) and the shape of the recess 130 will be described in detail later.

As shown in FIGS. 2 and 3, the semiconductor device has an interlayer insulating film 111 formed on the source region 105, the contact region 106, and the gate electrode 109 including the gate lead-out portion 109a. On the interlayer insulating film 111, the upper electrode 112 serving as a source electrode shown in FIG. 2 and the gate wiring layer 113 shown in FIG. 3 are formed as conductor patterns. The gate wiring layer 113 forms a part of the gate liner 13. In this embodiment, the gate liner 13 includes the gate wiring layer 113 and the gate lead-out portion 109a. The interlayer insulating film 111 has contact holes 111a and 111b. As shown in FIG. 2, the upper electrode 112 is electrically connected to the source region 105 and the contact region 106 through the contact hole 111a. As shown in FIG. 3, the gate wiring layer 113 is electrically connected to the gate lead-out portion 109a, that is, the gate electrode 109, through the contact hole 111b.

The semiconductor device has the peripheral region Rb covered with the protective film 115. The protective film 115 has a first opening for the upper electrode 112, and a second opening for the pads 12a to 12d.

On the second surface 100b of the semiconductor substrate 100, a lower electrode 114 is formed as a drain electrode electrically connected to the substrate 101. In this manner, the semiconductor device of this embodiment is configured by forming a vertical MOSFET having an n-channel type and inversion type trench gate structure.

In this embodiment, the n-type corresponds to the first conductivity type, and the p-type corresponds to the second conductivity type. Next, the operation of the semiconductor device will be described, and the structure will be further detailed.

In the semiconductor device, when a voltage higher than that of the upper electrode 112 is applied to the lower electrode 114, the PN junction formed between the base region 104 and the drift layer 102 enters a reverse conductive state, forming a depletion layer. When a low-level gate voltage (for example, 0 V) that is less than a threshold voltage Vth of the insulated gate structure is applied to the gate electrode 109, a current does not flow between the upper electrode 112 and the lower electrode 114.

To turn on the semiconductor device (i.e., vertical MOSFET), a high-level gate voltage equal to or higher than the threshold voltage Vth of the insulated gate structure is applied to the gate electrode 109 while a voltage higher than that of the upper electrode 112 is applied to the lower electrode 114. As a result, an inversion layer is formed in the base region 104 that contacts the gate trench 107 in which the gate electrode 109 is disposed. Then, electrons are supplied from the source region 105 through the inversion layer to the drift layer 102, thereby entering an on-state in which a current flows between the upper electrode 112 and the lower electrode 114.

To turn off the semiconductor device, the gate voltage applied to the gate electrode 109 is made lower than the threshold voltage Vth. As a result, the inversion layer formed in the base region 104 disappears, and the semiconductor device enters an off state.

At this time, in the semiconductor device of this embodiment, a sudden voltage change (dV/dt) occurs in the lower electrode 114, and a displacement current I flows to charge and discharge the capacitance C between the drift layer 102 and the base region 104.

Here, as shown in FIG. 5, a comparative semiconductor device is defined, in which no recess 130 is formed on the first surface 100a of the semiconductor substrate 100 in the peripheral region Rb, while the configuration of the active region Ra is the same as that of the first embodiment. That is, a semiconductor device in which the insulating film 120 does not have the second corner 121b is the comparative semiconductor device. FIG. 5 is a cross-sectional view of the comparative semiconductor device, corresponding to FIG. 4.

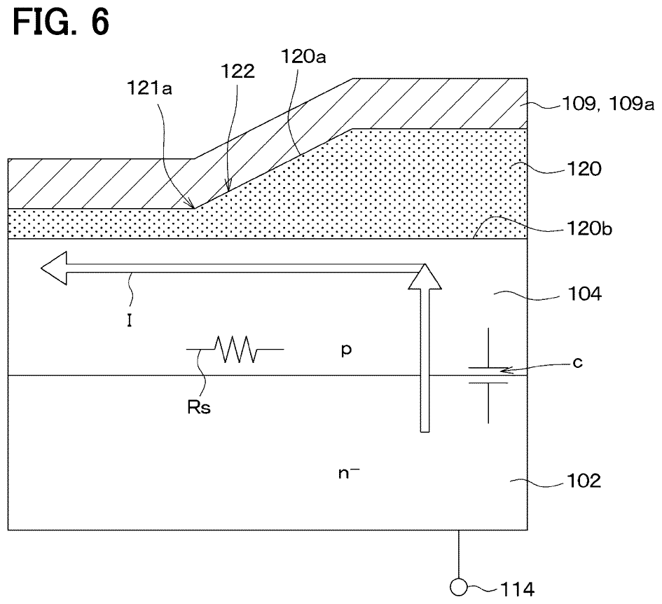

In the comparative semiconductor device, as shown in FIG. 6, the displacement current I in the peripheral region Rb flows below the insulating film 120 so as to be discharged from the contact region 106 in the active region Ra. In this case, a voltage ΔV expressed by Formula 1 is applied to the insulating film 120, in which the displacement current is represented by I and the resistance value of the semiconductor where the displacement current I flows is represented by Rs.

ΔV=I×Rs (Formula 1)

The displacement current I is expressed by Formula 2, where C represents the junction capacitance between the drift layer 102 and the base region 104, and Irr represents the recovery current.

I=C×dV/dt(+Irr) (Formula 2)

In the comparative semiconductor device, an electric field is likely to concentrate at the first corner 121a of the insulating film 120, and the insulating film 120 may be destroyed at the first corner 121a that is thin. That is, the comparative semiconductor device may have a low dV/dt resistance.

For this reason, in this embodiment, the recess 130 is formed on the first surface 100a of the semiconductor substrate 100 at the position corresponding to the first corner 121a. The insulating film 120 has the second corner 121b on the second surface 120b. Therefore, in this embodiment, the maximum voltage applied to the insulating film 120 can be reduced.

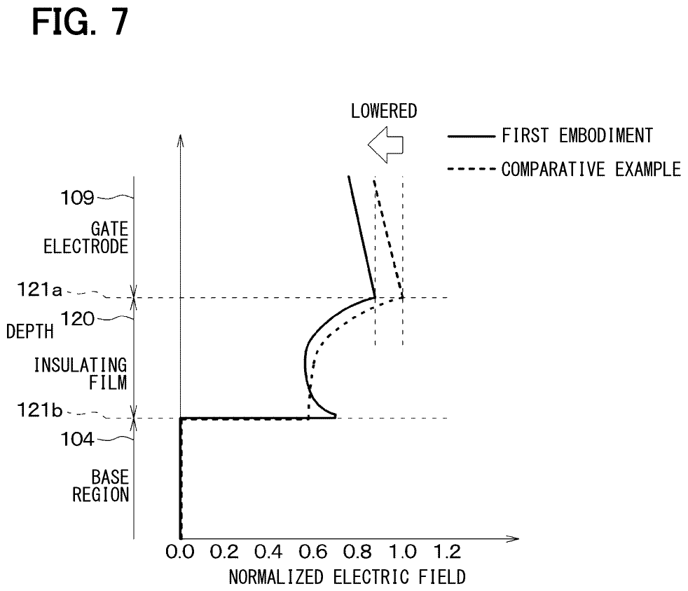

Specifically, the inventors conducted extensive research into the electric field along a normal direction to the first surface 100a of the semiconductor substrate 100, that passes through the first corner 121a of the insulating film 120, and obtained the results shown in FIG. 7.

FIG. 7 shows an electric field relative to a portion of the semiconductor device of the first embodiment taken along line VII-VII in FIG. 4, and an electric field relative to the comparative semiconductor device taken along line VII-VII in FIG. 5. In the comparative semiconductor device, the insulating film 120 does not have the second corner 121b. FIG. 7 shows the result when the location of the second corner 121b coincides with a virtual line K extended along the normal direction to pass through the first corner 121a, as shown in FIG. 5. In FIG. 4, the virtual line K is shown slightly offset from the first corner 121a and the second corner 121b, but in reality, it is assumed that the first corner 121a and the second corner 121b coincide with the virtual line K.

FIG. 7 shows the results when an angle between the surface direction of the first surface 100a of the semiconductor substrate 100 and the inclined portion 122 is set to a first angle θ1 of 30°, as shown in FIG. 4, and when an angle between the surface direction of the first surface 100a of the semiconductor substrate 100 and the side surface of the recess 130 is set to a second angle θ2 of 60°. Furthermore, FIG. 7 shows the results when a length from the first surface 100a of the semiconductor substrate 100 to the bottom surface 130a of the recess 130 is defined as a depth “d”, as shown in FIG. 4, and the depth d is set to 80 nm. FIG. 7 shows the results when the measurement temperature is −40° C. and the dV/dt is 150 kV/μs. In FIG. 7, the maximum voltage applied to the insulating film 120 of the comparative semiconductor device is used as a reference (that is, the normalized electric field is 1).

As shown in FIG. 7, in the comparative semiconductor device, since only the first corner 121a is formed on the first surface 120a of the insulating film 120, the electric field is concentrated at the first corner 121a of the insulating film 120. In contrast, in the semiconductor device of this embodiment, since the first corner 121a and the second corner 121b are formed on the insulating film 120, the electric field is concentrated at the first corner 121a and the second corner 121b of the insulating film 120. Therefore, according to the semiconductor device of this embodiment, the maximum voltage applied to the insulating film 120 can be reduced by increasing the number of locations where the electric field is concentrated. Thus, the insulating film 120 can be restricted from being destroyed.

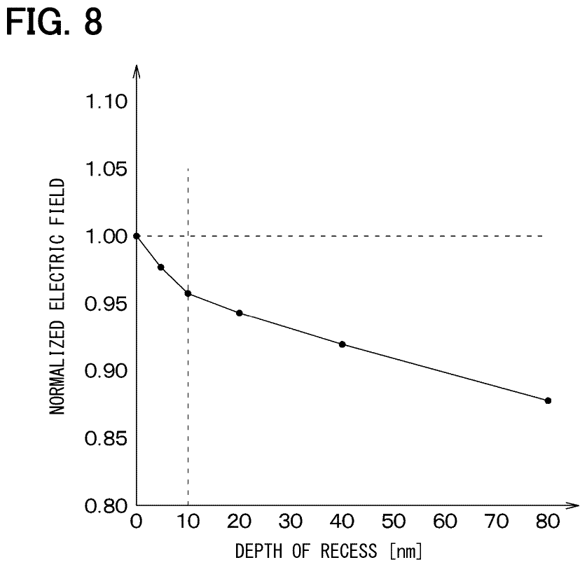

The present inventors also conducted extensive research into the depth d of the recess 130 and obtained the results shown in FIG. 8 representing simulations performed under the same conditions as those in FIG. 7 except for the depth d. FIG. 8 shows the results of investigating the maximum voltage applied to the insulating film 120 of the semiconductor device of the present embodiment, with the maximum voltage applied to the insulating film 120 of the comparative semiconductor device taken as the reference (i.e., the normalized electric field is 1).

As shown in FIG. 8, it is confirmed that the electric field decreases sharply as the depth d of the recess 130 increases in a range where the depth d is less than 10 nm. When the depth d of the recess 130 is within the range of 10 nm or more, the electric field gradually decreases as the depth d increases. For this reason, the depth d of the recess 130 is preferably set to 10 nm or more.

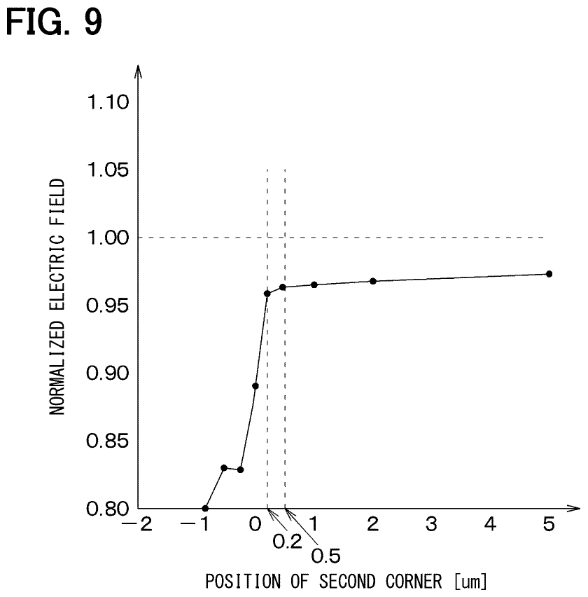

The inventors also conducted extensive research into the position of the second corner 121b and obtained the results shown in FIG. 9 representing the simulations performed under the same conditions as those in FIG. 7 except for the position of the second corner 121b. FIG. 9 shows the results of investigating the maximum voltage applied to the insulating film 120 of the semiconductor device of the present embodiment, with the maximum voltage applied to the insulating film 120 of the comparative semiconductor device taken as the reference (i.e., the normalized electric field is 1). The position of the second corner 121b in FIG. 9 is represented by a negative value when the second corner 121b is located adjacent to the active region Ra with respect to the virtual line K passing through the first corner 121a, and a positive value when the second corner 121b is located on the opposite side to the active region Ra, as shown in FIG. 4. In other words, in FIG. 4, the position of the second corner 121b is defined as a negative value when the second corner 121b is located to the left of the virtual line K, and as a positive value when the second corner 121b is located to the right of the virtual line K. Since the second corner 121b coincides with the virtual line K in FIG. 4, the position of the second corner 121b is zero in FIG. 9.

As shown in FIG. 9, it is confirmed that the electric field decreases when the position of the second corner 121b is 0.5 μm or less. The electric field decreases sharply when the position of the second corner 121b is 0.2 μm or less. For this reason, the position of the second corner 121b is preferably set to 0.5 μm or less, and more preferably to 0.2 μm or less. Also, as shown in FIG. 9, it is confirmed that the electric field further decreases when the value of the second corner 121b becomes negative. Therefore, the second corner 121b may be located closer to the active region Ra than the first corner 121a is. The electric field further decreases when the second corner 121b has a negative value because the insulating film 120 located below the first corner 121a becomes thicker.

According to the present embodiment, the insulating film 120 has the second corner 121b formed at the position corresponding to the first corner 121a. This makes it possible to increase the number of locations in the insulating film 120 where the electric field is concentrated, and to reduce the maximum electric field applied to the insulating film 120, thereby making it possible to restrict the insulating film 120 from being destroyed.

(1) In this embodiment, the recess 130 has the depth d of 10 nm or more. This makes it easier to reduce the maximum voltage applied to the insulating film 120.

(2) In this embodiment, the second corner 121b is formed at a position 0.5 μm or less from the virtual line K, which makes it easier to reduce the maximum voltage applied to the insulating film 120. In this case, by forming the second corner 121b at a position 0.2 μm or less from the virtual line K, the maximum voltage applied to the insulating film 120 can be made even smaller.

### Second Embodiment

A second embodiment will be described. In this embodiment, the shape of the recess 130 is changed from that of the first embodiment. The remaining configurations are similar to those of the first embodiment and will thus not be described repeatedly.

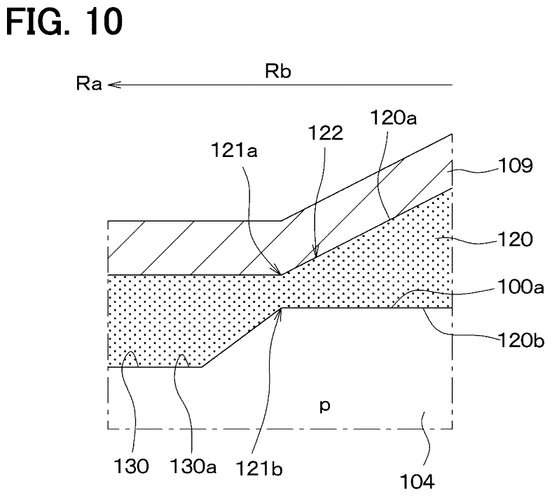

In the semiconductor device of this embodiment, as shown in FIG. 10, the recess 130 is formed so that the bottom surface 130a is located adjacent to the active region Ra with respect to the second corner 121b (that is, the first corner 121a). The first surface 100a of the semiconductor substrate 100 has a flat surface in an area facing the inclined portion 122.

In this way, even if the recess 130 is located closer to the active region Ra than the first corner 121a, the same effects as in the first embodiment can be obtained. In this embodiment, when the position of the second corner 121b has a positive value, the first corner 121a opposes the recess 130. Therefore, the maximum voltage applied to the insulating film 120 can be easily reduced by forming the second corner 121b at a position −0.5 μm or more from the virtual line K. In this case, the maximum voltage applied to the insulating film 120 can be made even smaller by forming the second corner 121b at a position −0.2 μm or more away from the virtual line K.

### Third Embodiment

A third embodiment will be described. In this embodiment, the shape of the recess 130 is changed from that of the first embodiment. The remaining configurations are similar to those of the first embodiment and will thus not be described repeatedly.

The semiconductor device of this embodiment has the same basic configuration as that of the first embodiment. In this embodiment, the second angle θ2 is specified as the inclination angle.

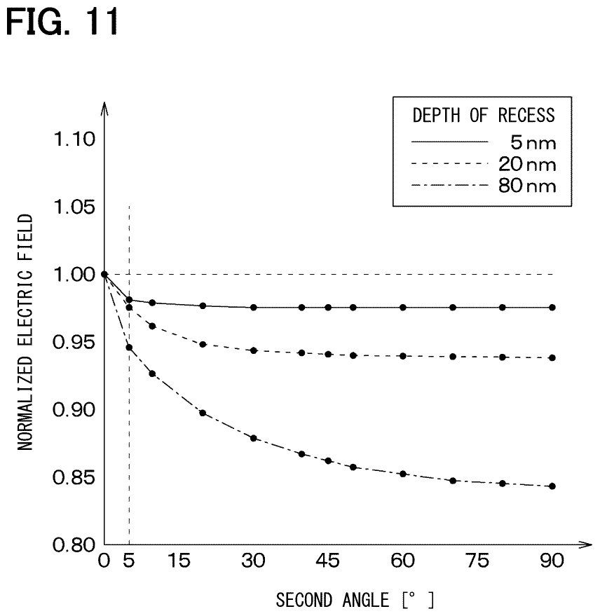

Specifically, the inventors have conducted extensive research into the second angle θ2 and obtained the results shown in FIG. 11 representing the simulations performed under the same conditions as those in FIG. 7 except for the second angle θ2. FIG. 11 shows the results of investigating the maximum voltage applied to the insulating film 120 of the semiconductor device of the present embodiment, with the maximum voltage applied to the insulating film 120 of the comparative semiconductor device taken as the reference (i.e., the normalized electric field is 1).

As shown in FIG. 11, it is confirmed that the electric field tends to become smaller as the depth d of the recess 130 increases. It is also confirmed that the electric field tends to become smaller as the second angle θ2 increases. More specifically, it is confirmed that the electric field can be sufficiently low if the depth d of the recess 130 is 5 nm or more and the second angle θ2 is 5° or more. Furthermore, since the electric field tends to become smaller as the depth d of the recess 130 becomes deeper, it has been confirmed that even when the depth d of the recess 130 is set to 10 nm or more, the electric field can be made sufficiently low by setting the second angle θ2 to 5° or more. For this reason, in this embodiment, the second angle θ2 is set to 5° or more. In order to restrict the manufacturing process from becoming complicated, the second angle θ2 is preferably set to 90° or less.

According to the present embodiment, since the insulating film 120 has the second corner 121b, it is possible to obtain the same effects as those of the first embodiment.

(1) In this embodiment, if the second angle θ2 is set to 5° or more, the electric field applied to the insulating film 120 can be easily made sufficiently small.

### Fourth Embodiment

A fourth embodiment will be described. In this embodiment, the recess 130 is modified from the first embodiment. The remaining configurations are similar to those of the first embodiment and will thus not be described repeatedly.

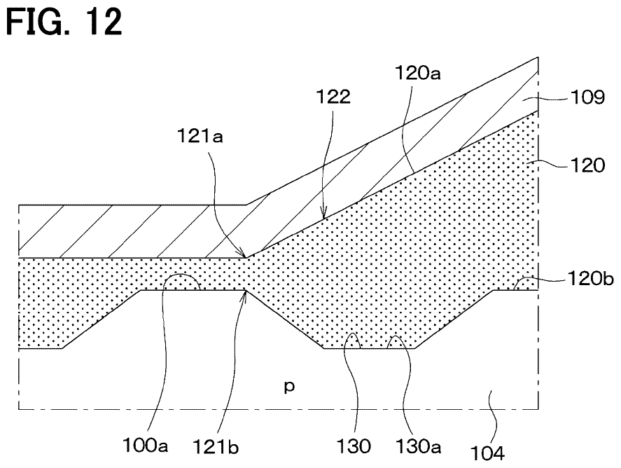

In the semiconductor device of this embodiment, as shown in FIG. 12, plural recesses 130 are formed along the surface direction of the first surface 100a of the semiconductor substrate 100. In this embodiment, one of the recesses 130 is formed such that the first corner 121a and the second corner 121b coincide with each other in the normal direction.

According to the present embodiment, since the insulating film 120 has the second corner 121b, it is possible to obtain the same effects as those of the first embodiment. As in this embodiment, the recesses 130 may be arranged along the surface direction of the first surface 100a of the semiconductor substrate 100.

### Modification of Fourth Embodiment

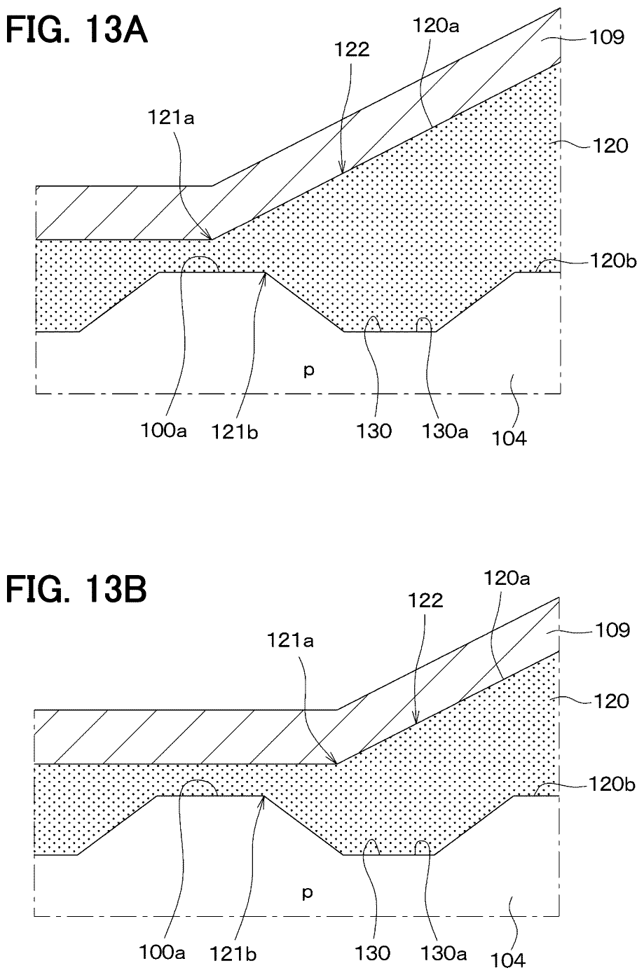

A modification of the fourth embodiment will be described below. As shown in FIG. 13A, the recesses 130 may be formed such that the first corner 121a opposes the first surface 100a of the semiconductor substrate 100. As shown in FIG. 13B, the recesses 130 may be formed such that the first corner 121a opposes the bottom surface 130a of the recess 130.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, a vertical MOSFET is given as an example of a switching element provided in the active region Ra, but the switching element may be a vertical IGBT or the like, or may be configured by combining multiple types of elements. Furthermore, the switching element may be of a planar type instead of a trench gate structure. Furthermore, the first conductivity type may be p-type, and the second conductivity type may be n-type.

The semiconductor substrate 100 is made of SiC or Si in the embodiment. However, the semiconductor substrate 100 may be made of, for example, a gallium nitride substrate. However, SiC requires a high operating voltage, and the voltage applied to the insulating film 120 tends to be particularly high. Therefore, each of the embodiments is useful when the semiconductor substrate 100 is made of SiC.

The inclined portion 110a of the field insulating film 110 may be formed so that the thickness increases stepwise rather than gradually.

The inclined portion 122 of the insulating film 120 may be composed of only the field insulating film 110.

In each of the embodiments, the recess 130 may have a depth d of 10 nm or less. Furthermore, the position of the second corner 121b may be changed as appropriate. Even in such a semiconductor device, by forming the second corner 121b in the insulating film 120, the number of locations in the insulating film 120 where the electric field is concentrated can be increased, so that the insulating film 120 can be restricted from being destroyed.

The above embodiments can be appropriately combined. For example, the second embodiment may be combined with the third and/or fourth embodiments, and the third embodiment may be combined with the fourth embodiment.

What is claimed is:

1. A semiconductor device comprising:
a semiconductor substrate having an active region and a peripheral region surrounding an outer periphery of the active region;
a switching element formed in the active region and having a gate electrode; and
an insulating film formed in the peripheral region, wherein
the insulating film has a first surface opposite to the semiconductor substrate and a second surface adjacent to the semiconductor substrate,
the insulating film includes an inclined portion having a thickness that gradually increases as extending away from the active region,
the insulating film has a first corner at which the thickness of the insulating film begins to increase on the first surface,
the gate electrode is extended from the active region to the peripheral region and is located on the inclined portion of the insulating film,
the semiconductor substrate has a recess, and an open end of the recess is located at a position corresponding to the first corner,
the insulating film is arranged in the recess to cover the open end, and
the insulating film has a second corner on the second surface to cover the open end.

2. The semiconductor device according to claim 1, wherein the recess has a depth of 10 nm or more from a first surface of the semiconductor substrate.

3. The semiconductor device according to claim 1, wherein
the recess has a bottom surface located opposite to the active region relative to the second corner,
a virtual line is defined to pass through the first corner and extend along a normal direction to a surface direction of a first surface of the semiconductor substrate, and
the second corner is located at a position of 0.5 μm or less from the virtual line, when the position is defined as a positive value within a range opposite to the active region with respect to the virtual line and a negative value within a range adjacent to the active region with respect to the virtual line.

4. The semiconductor device according to claim 3, wherein the second corner is located at a position of 0.2 μm or less from the virtual line.

5. The semiconductor device according to claim 1, wherein
the recess has a bottom surface located adjacent to the active region relative to the second corner,
a virtual line is defined to pass through the first corner and extend along a normal direction to a surface direction of a first surface of the semiconductor substrate, and
the second corner is located at a position of −0.5 μm or more from the virtual line, when the position is defined as a positive value within a range opposite to the active region with respect to the virtual line and a negative value within a range adjacent to the active region with respect to the virtual line.

6. The semiconductor device according to claim 5, wherein the second corner is located at a position of −0.2 μm or more from the virtual line.
